(19) United States
(12) Patent Application Publication
(10) Pub. No.: US 2024/0241696 A1
(43) Pub. Date: Jul. 18, 2024

(54) RANDOM NUMBER GENERATOR AND RANDOM NUMBER GENERATING METHOD

(71) Applicants: BOE TECHNOLOGY GROUP CO., LTD., Beijing (CN); Peking University, Beijing (CN)

(72) Inventors: Xiangye WEI, Beijing (CN); Ming ZHAO, Beijing (CN); Wei HU, Beijing (CN); Yimao CAI, Beijing (CN); Shengyi HE, Beijing (CN); Yiming BAI, Beijing (CN); Xinyu ZHOU, Beijing (CN)

(73) Assignees: BOE TECHNOLOGY GROUP CO., LTD., Beijing (CN); Peking University, Beijing (CN)

(21) Appl. No.: 18/015,200

(22) PCT Filed: Oct. 27, 2021
(86) PCT No.: PCT/CN2021/126838

§ 371 Date: Jan. 9, 2023

(51) Int. Cl. G06F 7/58; H03K 19/20

(52) U.S. Cl. CPC G06F 7/586; H03K 19/20

(57) ABSTRACT

A random number generator includes: a random number generating circuit used for generating a pulse signal based on a control word and generating a random number signal according to the pulse signal, the pulse signal including a first frequency signal and a second frequency signal that appear alternately, and proportions of the first frequency signal and the second frequency signal being controlled by the control word; and a feedback update circuit used for updating the control word based on the random number signal output by the random number generating circuit.

### CROSS-REFERENCE TO RELATED APPLICATION

This application is a national phase entry under 35 USC 371 of International Patent Application No. PCT/CN2021/126838, filed on Oct. 27, 2021, which is incorporated herein by reference in its entirety.

### TECHNICAL FIELD

The present disclosure relates to a random number generator and random number generating method.

### BACKGROUND

Encryption of information is accomplished by software and hardware, the hardware are responsible to provide random numbers, and the software are responsible to generate more complex keys according to the random numbers provided by the hardware and use the keys to encrypt the information.

At present, generation of the random numbers may be realized by a random number generator. The random number generator includes a random number generating circuit and a post processing circuit, and the post processing circuit is used for further processing the random numbers generated by the random number generating circuit to improve randomness of the random numbers. For example, the post processing circuit is implemented by using a linear feedback shift register. Although the randomness of the random numbers processed by the linear feedback shift register is increased, a magnitude of the increase is not large, and the randomness of the random numbers generated by the whole random number generator is still not high enough.

### SUMMARY

Some embodiments of the present disclosure provide a random number generator and a random number generating method.

At least one embodiment of the present disclosure provides a random number generator. The random number generator includes:
a random number generating circuit used for generating a pulse signal based on a control word and generating a random number signal according to the pulse signal; the pulse signal including a first frequency signal and a second frequency signal that appear alternately, and proportions of the first frequency signal and the second frequency signal being controlled by the control word; and
a feedback update circuit used for updating the control word based on the random number signal output by the random number generating circuit.

For example, the feedback update circuit includes:
a frequency division sub-circuit used for performing frequency division on the random number signal generated by the random number generating circuit and outputting a frequency division signal obtained by the frequency division;
a linear congruence sub-circuit used for determining a linear congruence signal by using the frequency division signal output by the frequency division sub-circuit; and
a feedback output sub-circuit used for updating the control word by using the linear congruence signal output by the linear congruence sub-circuit.

The frequency division sub-circuit is electrically connected to the linear congruence sub-circuit, the feedback output sub-circuit and the random number generating circuit, and the feedback output sub-circuit is electrically connected to the linear congruence sub-circuit and the random number generating circuit.

For example, the linear congruence sub-circuit is used for determining the linear congruence signal by:
performing linear congruence processing on a linear congruence signal of a previous period, and performing an exclusive OR (XOR) operation on a signal composed of a result of the linear congruence processing and the frequency division signal output by the frequency division sub-circuit, so as to obtain a linear congruence signal of a current period.

For example, the control word includes a first coefficient, and the first coefficient is used for controlling the proportions of the first frequency signal and the second frequency signal in the pulse signal;
the feedback output sub-circuit is used for updating the first coefficient by using N bits of the linear congruence signal output by the linear congruence sub-circuit; N is less than or equal to a number of bits of the first coefficient, and N is greater than half of the number of bits of the first coefficient.

For example, the first coefficient is fractional bits of the control word, a number of fractional bits of the control word is 8, and the N is equal to 8.

In some embodiments, the feedback update circuit is implemented by using a 32-bit field programmable gate array.

For example, the random number generating circuit includes:
a plurality of pulse sub-circuits, one of the plurality of pulse sub-circuits being a clock sub-circuit used for outputting a clock pulse signal, and remaining pulse sub-circuits of the plurality of pulse sub-circuits each being a frequency sub-circuit used for outputting a frequency pulse signal;
a first processing sub-circuit electrically connected to the remaining pulse sub-circuits and used for performing first processing on the frequency pulse signals output by the frequency sub-circuits; the first processing including at least one of XOR, exclusive NOR (XNOR) or NOT AND (NAND); and
a second processing sub-circuit electrically connected to the clock pulse signal and used for sampling an output of the first processing sub-circuit based on the clock pulse signal to obtain the random number signal.

For example, the feedback output sub-circuit is used for periodically updating control words of the remaining pulse sub-circuits by using the linear congruence signal output by the linear congruence sub-circuit.

For example, the feedback output sub-circuit is used for updating the control words of the remaining pulse sub-circuits in turn; the feedback output sub-circuit updates a control word of one of the remaining pulse sub-circuits in each period.

For example, a pulse sub-circuit of the remaining pulse sub-circuits includes:
a signal generator and a frequency synthesizer; the frequency synthesizer being electrically connected to the signal generator, the feedback update circuit and the first processing sub-circuit.

The signal generator is used for generating reference pulse signals with uniform spaced phases in response to an initial pulse signal.

The frequency synthesizer is used for generating the pulse signal in response to the reference pulse signals and the control word.

The control word includes a first coefficient and a second coefficient.

The pulse signal includes the first frequency signal generated based on the reference pulse signals and the second coefficient and the second frequency signal generated based on the reference pulse signals and the second coefficient, and the proportions of the first frequency signal and the second frequency signal in the pulse signal are controlled by the first coefficient.

In some embodiments, in the plurality of pulse sub-circuits, a pulse sub-circuit generating a pulse signal with a minimum frequency is the clock sub-circuit.

In some embodiments, the plurality of pulse sub-circuits are each a digitally controlled oscillator.

In some embodiments, the second processing sub-circuit includes a sampling sub-circuit; the sampling sub-circuit includes a D flip-flop, an input terminal of the D flip-flop is connected to the first processing sub-circuit, and a control terminal of the D flip-flop is connected to the clock sub-circuit.

In some embodiments, the signal generator is a ring oscillator.

At least one embodiment of the present disclosure provides a random number generating method. The random number generating method includes:
generating a pulse signal based on a control word; the pulse signal including a first frequency signal and a second frequency signal that appear alternately, and proportions of the first frequency signal and the second frequency signal being controlled by the control word;
generating a random number signal according to the pulse signal; and
updating the control word based on the random number signal.

For example, updating the control word based on the random number signal includes:
performing frequency division on the random number signal;
outputting a frequency division signal obtained by the frequency division;
determining a linear congruence signal by using the frequency division signal; and
updating the control word by using the linear congruence signal.

For example, determining the linear congruence signal by using the frequency division signal includes:
performing linear congruence processing on a linear congruence signal of a previous period; and
performing an exclusive OR (XOR) operation on a signal composed of a result of the linear congruence processing and the frequency division signal, so as to obtain a linear congruence signal of a current period.

For example, the control word includes a first coefficient, and the first coefficient is used for controlling the proportions of the first frequency signal and the second frequency signal in the pulse signal.

Updating the control word by using the linear congruence signal includes:
updating the first coefficient by using N bits of the linear congruence signal; N being less than or equal to a number of bits of the first coefficient, and N being greater than half of the number of bits of the first coefficient.

For example, the first coefficient is fractional bits of the control word, a number of fractional bits of the control word is 8, and N is equal to 8.

For example, the pulse signal includes frequency pulse signals and a clock pulse signal.

Generating the random number signal according to the pulse signal includes:
performing first processing on the frequency pulse signals, the first processing including at least one of XOR, exclusive NOR (XNOR) or NOT AND (NAND); and
sampling an output of the first processing based on the clock pulse signal to obtain the random number signal.

### BRIEF DESCRIPTION OF THE DRAWINGS

FIG. 1 is a schematic diagram showing a structure of a random number generator, in accordance with the embodiments of the present disclosure;

FIG. 2 is a schematic diagram showing a structure of a feedback update circuit, in accordance with the embodiments of the present disclosure;

FIG. 3 is a schematic diagram showing a structure of a random number generating circuit, in accordance with the embodiments of the present disclosure;

FIG. 4 is a schematic diagram showing a structure of a pulse sub-circuit, in accordance with the embodiments of the present disclosure;

FIG. 5 is a schematic diagram showing a structure of a ring oscillator, in accordance with the embodiments of the present disclosure;

FIG. 6 is a diagram showing waveforms of K reference pulse signals, with uniform spaced phases, generated by the ring oscillator in FIG. 5;

FIG. 7 is a schematic diagram showing a principle of synthesizing a pulse signal by using a frequency synthesizer, in accordance with the embodiments of the present disclosure;

FIG. 8 is a schematic diagram showing a structure of a frequency synthesizer, in accordance with the embodiments of the present disclosure;

FIG. 9 is a detailed schematic diagram of a random number generating circuit, in accordance with the embodiments of the present disclosure;

FIG. 10 is a diagram showing a NIST test of a random number generated by a random number generator, in accordance with the embodiments of the present disclosure; and

FIG. 11 is a flow diagram of a random number generating method, in accordance with the embodiments of the present disclosure.

### DETAILED DESCRIPTION

In order to make principles and benefits of the present disclosure clear, the embodiments of the present disclosure will be described in detail below with reference to the drawings.

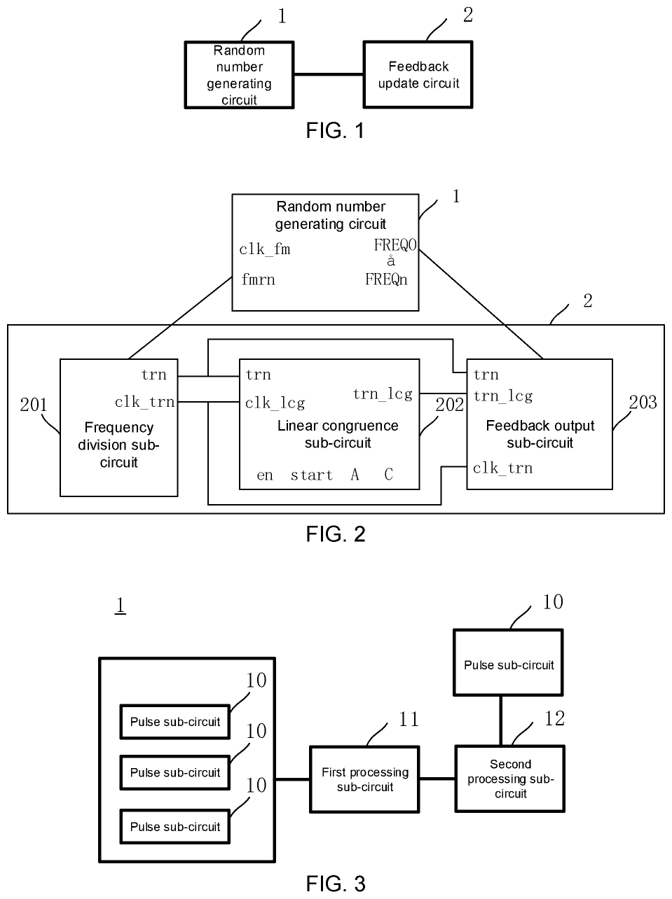

FIG. 1 is a schematic diagram showing a structure of a random number generator provided in the embodiments of the present disclosure. Referring to FIG. 1, the random number generator includes a random number generating circuit 1 and a feedback update circuit 2, and the random number generating circuit 1 is electrically connected to the feedback update circuit 2.

The random number generating circuit 1 is used for generating a pulse signal based on a control word and generating a random number signal according to the pulse signal; the pulse signal includes a first frequency signal and a second frequency signal that appear alternately, and proportions of the first frequency signal and the second frequency signal are controlled by the control word. The feedback update circuit 2 is used for updating the control word based on the random number signal output by the random number generating circuit 1.

In the embodiments of the present disclosure, the control word of the random number generating circuit is updated based on the random number signal output by the random number generating circuit, so that the control word of the random number generating circuit is always changing. Compared with a control word of a random number generating circuit that is unchanged, randomness of the random number generating circuit in the embodiments of the present disclosure is fundamentally improved, so that randomness of the random number output by the random number generator is improved.

It is worth noting that the random number signal output by the random number generating circuit 1 is further used as an output of the random number generator in addition to being used as an input of the feedback update circuit 2.

FIG. 2 is a schematic diagram showing a structure of the feedback update circuit 2 provided in the embodiments of the present disclosure. Referring to FIG. 2, the feedback update circuit 2 includes a frequency division sub-circuit 201, a linear congruence sub-circuit 202 and a feedback output sub-circuit 203. The frequency division sub-circuit 201 is electrically connected to the linear congruence sub-circuit 202, the feedback output sub-circuit 203 and the random number generating circuit 1, and the feedback output sub-circuit 203 is electrically connected to the linear congruence sub-circuit 202 and the random number generating circuit 1.

The frequency division sub-circuit 201 is used for performing frequency division on the random number signal generated by the random number generating circuit 1 and outputting a frequency division signal obtained by the frequency division; the linear congruence sub-circuit 202 is used for determining a linear congruence signal by using the frequency division signal output by the frequency division sub-circuit 201; and the feedback output sub-circuit 203 is used for updating the control word by using the linear congruence signal output by the linear congruence sub-circuit 202.

In this implementation manner, the frequency division processing is performed on the random number signal output by the random number generating circuit, then the linear congruence signal is determined by using the frequency division signal, and then the control word is updated by using the linear congruence signal. In this way, the linear congruence signal has the good randomness after linear congruence processing, so that it is possible to improve randomness of the control word by using the linear congruence signal to update the control word, and improve randomness of an output of the whole circuit.

In some possible implementation manners, the frequency division sub-circuit 201 is used for performing frequency division collection on a single-bit random number (i.e., fmrn in FIG. 2) output by the random number generating circuit 1. That is, serial-parallel conversion is performed on the random number signal, thereby outputting data of a plurality of bits (e.g., 16 bits, 8 bits, 4 bits) at one time, and the data of the plurality of bits is the frequency division signal (i.e., trn in FIG. 2).

For example, the frequency division sub-circuit 201 is implemented by a shift register, and the shift register may output data of the set number of bits after collecting the data of the set number of bits. For example, the shift register may receive the single-bit random number, and output data of 8 bits as the frequency division signal after collecting the data of 8 bits.

In some possible implementation manners, the linear congruence sub-circuit is used for determining the linear congruence signal by a following way:
performing the linear congruence processing on a linear congruence signal of a previous period, and performing an exclusive OR (XOR) operation on a signal composed of a result of the linear congruence processing and the frequency division signal output by the frequency division sub-circuit, so as to obtain a linear congruence signal of a current period.

For example, the linear congruence sub-circuit 202 is used for determining the linear congruence signal according to the following formula:

$${X}_{n + 1} = [ ( A * {X}_{n} + C ) mod M ] XOR trn \qquad ( 1 )$$

where A, C, M are each a preset parameter, Xₙ₊₁ is the linear congruence signal of the current period, Xₙ is the linear congruence signal of the previous period, trn is composed of the frequency division signals output by the frequency division sub-circuit 201 (for example, which is composed of frequency division signals of a plurality of periods, such as frequency division signals of four periods). It is worth noting that in a case where the linear congruence signal is firstly determined according to the formula, Xₙ may be a preset value, or directly use trn.

The linear congruence formula provided here is actually an improved linear congruence formula, which performs the XOR operation on the frequency division signal and the result of the linear congruence processing, and the result of the linear congruence is obtained based on the linear congruence signal of the previous period. With this formula, on the basis of improving the randomness through the linear congruence, an output of the linear congruence sub-circuit is caused to change near an input (i.e., the frequency division signals trn output by the frequency division sub-circuit 201) of the linear congruence sub-circuit by using the XOR operation, so as to avoid a situation that randomness of the random number signal is reduced due to a great change of the control word.

In the determination of the linear congruence, the larger a value of M, the larger a random period of the linear congruence. Here, the feedback update circuit is implemented by a 32-bit system, and the parameter M adopts 32 bits that is the maximum bits to ensure maximization of the value of M, thereby increasing the random period to ensure the randomness.

That is, the formula may be represented as:

$${X}_{n + 1} = [ ( A * {X}_{n} + C ) mod ( {2}^{32} ) ] XOR trn\_bit [ 31 : 0 ] .$$

For example, A=1664525, C=1013904223, and M=4294967296.

For example, the feedback update circuit is implemented by using a 32-bit field programmable gate array (FPGA). For example, by using the PYNQ-Z2 FPGA of Xilinx, using Vivado development software and programming in the Verilog hardware description language, the System Verilog language and the Python language, the feedback update circuit is implemented.

Although the linear congruence sub-circuit 202 processes with 32 bits as a processing period, the input and the output of the linear congruence sub-circuit 202 may not be 32 bits per period. Referring to FIG. 2, the frequency division sub-circuit 201 and the feedback output sub-circuit 203 may use a same clock signal clk_trn, the linear congruence sub-circuit 202 may use a clock signal clk_lcg, and the clk_lcg and the clk_trn may be a same clock signal. The frequency division sub-circuit 201 writes data once at each rising edge of the clock signal, and the linear congruence sub-circuit 202 performs the linear congruence processing once every four rising edges. That is, an actual frequency of the linear congruence processing is ¼ of a frequency at which the frequency division sub-circuit 201 writes the data.

According to the structure in FIG. 2, an output terminal (i.e., a terminal represented by trn) of the frequency division sub-circuit 201 is connected to both the linear congruence sub-circuit 202 and the feedback output sub-circuit 203. In this way, the feedback output sub-circuit 203 may not only use the linear congruence signal trn_lcg output by the linear congruence signal sub-circuit to update control words FREQ0 to FREQn, but also use the frequency division signal trn to update the control words without the linear congruence processing. For example, the FREQn may be FREQ10. That is, there are eleven control 20) words in total that need to be updated.

Referring to FIG. 2, the linear congruence sub-circuit 202 further has an enable terminal (represented by en), a start terminal (represented by start), and setting terminals (respectively represented by A and C) of the parameter A and the parameter C. The start terminal is used for starting the linear congruence sub-circuit, when the enable terminal is activated, the linear congruence sub-circuit starts to work, so that the feedback output sub-circuit 203 uses the linear congruence signal trn_lcg output by the linear congruence sub-circuit to update the control word; when the enable port is not activated, the feedback output sub-circuit 203 uses the frequency division signal trn to update the control word.

In general, the number of bits of the output of the linear congruence sub-circuit 202 is related to the number of bits of the control word, and the number of bits of the input of the linear congruence sub-circuit 202 is generally equal to the number of bits of the output of the linear congruence sub-circuit 202.

For example, the control word is composed of a second coefficient and a first coefficient. The feedback output sub-circuit is used for updating the first coefficient by using N bits of the linear congruence signal output by the linear congruence sub-circuit; N is less than or equal to the number of bits of the first coefficient, and N is greater than half of the number of bits of the first coefficient. N bits of the linear congruence signal are at least part of the linear congruence signal.

For example, the first coefficient is fractional bits of the control word. The number of bits that are updated is less than or equal to the number of the fractional bits of the control word, so as to avoid being counterproductive due to a great amplitude of the change of the control word. The number of bits that are updated is greater than half of the number of fractional bits of the control word, so as to avoid being harmful to the improvement of the randomness due to a little amplitude of the change of the control word.

For example, the number of fractional bits of the control word is 8, and the N is equal to 8.

The number of bits of the control word is 16, which includes 8 integral bits and 8 fractional bits. During updating, 8 bits are used to update the fractional bits. The manner of updating may be adding, and the integer bits may be updated by carry. Of course, this is only one implementation manner of the control word, in other manners, the total number of bits of the control word and the number of fractional bits therein may be both set according to needs, and N is not greater than the number of fractional bits.

However, the linear congruence sub-circuit 202 receives the data of 8 bits, input by the frequency division sub-circuit 201 in each period (that is, the clock signal goes through a rising edge), once so as to obtain data of 32 bits after four periods (i.e., four beats). Thus, the linear congruence sub-circuit 202 performs the linear congruence processing once by using the data of 32 bits. The feedback output sub-circuit 203 uses a same period as the frequency division sub-circuit 201 and reads 8 bits, from the linear congruence signal obtained by the linear congruence processing, each time for updating the control word.

Of course, the aforementioned description that N is equal to 8 is merely an example, and N may be another number of bits.

In some possible implementation manners, the feedback output sub-circuit 203 is used for periodically updating the control word by using the linear congruence signal output by the linear congruence sub-circuit 202.

For example, in a case where the feedback output sub-circuit 203 periodically updates the control word, an update period used by the feedback output sub-circuit 203 may be determined according to needs. For example, the update period is a constant value or adaptively determined according to the control word. For example, in a case where there are two control words FREQ0 and FREQ1, the update period may be set as a result of FREQ1 divided by 32 bytes. For another example, in a case where there are three control words FREQ0 to FREQ2, the update period may be set as a product of FREQ2 multiplied by 16 bytes. The determine manners of the update period here are merely examples. A unit of the update period may also be set according to needs, which is, for example, milliseconds.

The feedback output sub-circuit 203 is used for updating control words of pulse sub-circuits in turn, and a control word of one of the pulse sub-circuits is updated in each period. The sequential update makes the control words of the sub-circuits different, which results in different outputs when sampling different sub-circuits, thereby improving the randomness.

For example, the feedback output sub-circuit 203 may be connected to control terminals of the random number generating circuit 1 each corresponding to a respective control word, so as to update the control words in sequence.

FIG. 3 is a schematic diagram showing a structure of the random number generating circuit 1 provided in the embodiments of the present disclosure. Referring to FIG. 3, the random number generating circuit 1 includes the plurality of pulse sub-circuits 10, a first processing sub-circuit 11 and a second processing sub-circuit 12, and the first processing sub-circuit 11 is electrically connected to the second processing sub-circuit 12.

Each of the plurality of pulse sub-circuits 10 generates a pulse signal based on the control word. One of the plurality of pulse sub-circuits 10 is a clock sub-circuit that is electrically connected to the second processing sub-circuit 12 and used for outputting a clock pulse signal (i.e., clk_fm in FIG. 2), and remaining pulse sub-circuits of the plurality of pulse sub-circuits 10 are each a frequency sub-circuit that is electrically connected to the first processing sub-circuit 11 and used for outputting a frequency pulse signal.

The first processing sub-circuit 11 is used for performing first processing on the frequency pulse signals output by the frequency sub-circuits, and the first processing includes at least one of XOR, exclusive NOR (XNOR) or NOT AND (NAND).

The second processing sub-circuit 12 is used for sampling an output of the first processing sub-circuit 11 based on the clock pulse signal to obtain the random number signal.

In this implementation manner, the first processing sub-circuit is used for performing logical operation such as XOR or XNOR on pulse signals, and then the sampling is performed, so as to improve an entropy value of bits in the output signal and ensure randomness of the signal.

For example, a pulse signal, generated by the plurality of pulse sub-circuits 10, with a minimum frequency serves as the clock pulse signal.

For example, the pulse sub-circuit 10 may be a digitally controlled oscillator (DCO).

For example, the plurality of pulse sub-circuits each include a frequency mixing (FM) sub-circuit, and the frequency mixing sub-circuit may be realized by using a technology of direct frequency average (DFA).

In some possible implementation manners, access states of pulse sub-circuits (the frequency sub-circuits) may be configured. By configuring the access state of each pulse sub-circuit, configurability of the random number generator is improved. As a result, the output is different under different configurations, thereby improving the randomness.

For example, output terminals of the pulse sub-circuits are each connected to a switch, so as to control whether each pulse sub-circuit is connected to the first sub-circuit to participate in the first processing of the first processing sub-circuit.

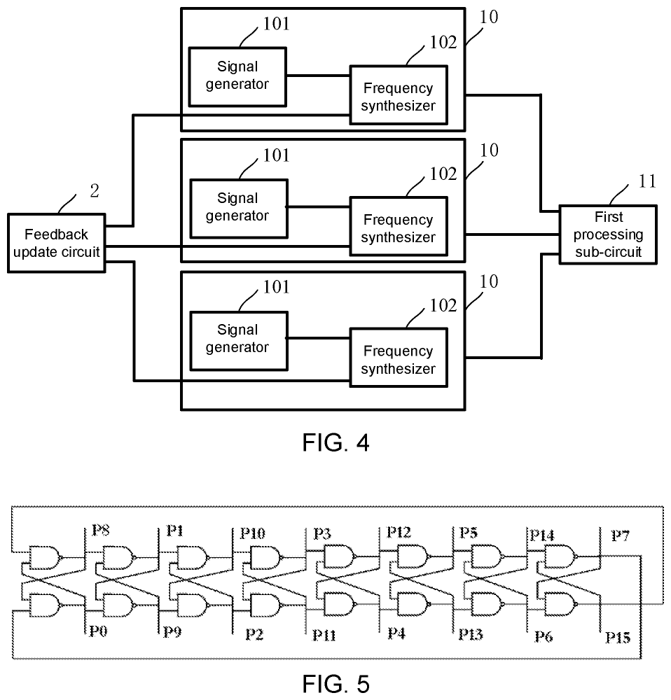

FIG. 4 is a schematic diagram showing a structure of the pulse sub-circuit 10 provided in the embodiments of the present disclosure. Referring to FIG. 4, the pulse sub-circuit 10 includes a signal generator 101 and a frequency synthesizer 102. The frequency synthesizer 102 is electrically connected to the signal generator 101, the feedback update circuit 2 and the first processing sub-circuit 11.

The signal generator 101 generates reference pulse signals with uniform spaced phases in response to an initial pulse signal. The frequency synthesizer 102 generates the pulse signal in response to the reference pulse signals with uniform spaced phases and the control word.

The control word includes the first coefficient and the second coefficient. The pulse signal includes the first frequency signal generated based on the reference pulse signals with the uniform spaced phases and the second coefficient, and the second frequency signal generated based on the reference pulse signals with the uniform spaced phases and the second coefficient; the proportions of the first frequency signal and the second frequency signal in the pulse signal are controlled by the first coefficient.

In this implementation manner, the pulse sub-circuit is composed of two portions. The signal generator is responsible to generate the reference pulse signals with the uniform spaced phases, and the frequency synthesizer is responsible to generate the pulse signal according to the reference pulse signals with the uniform spaced phases and the control word.

For example, the initial pulse signal may be generated by using a voltage-controlled oscillator. For example, the initial pulse signal may be generated by using an inductor-capacitor voltage controlled oscillator (LCVCO) as a vibration source. That is, the pulse sub-circuit may further include the voltage-controlled oscillator, and an output terminal of the voltage-controlled oscillator is electrically connected to an input terminal of the signal generator. Different pulse sub-circuits each generate an initial pulse signal by using a different LCVCO, and each initial pulse signal passes through a different signal generator, so that the reference pulse signals with uniform spaced phases in each pulse sub-circuit each have a different initial phase and a different noise characteristic. As a result, unpredictability of the output of the whole random number generating circuit is increased.

For example, the signal generator 101 may be a ring oscillator (RO). FIG. 5 is a schematic diagram showing a structure of the ring oscillator. Referring to FIG. 5, the ring oscillator includes a plurality of NAND gates, and the plurality of NAND gates are connected to one another to form a loop. The ring oscillator has a plurality of pins P0 to P15; one pin of the plurality of pins may serve as an input terminal to input an initial pulse signal, and the initial pulse signal is delayed by passing through the NAND gates; other pins the plurality of pins serve as output terminals to output a plurality of reference pulse signals, and the plurality of reference pulse signals are the reference pulse signals with the uniform spaced phases.

The reference pulse signals with the uniform spaced phases are refer to that the plurality of pulse signals generated by the signal generator 101 each have a same phase variation, and initial phases of the pulse signals have an equal interval therebetween.

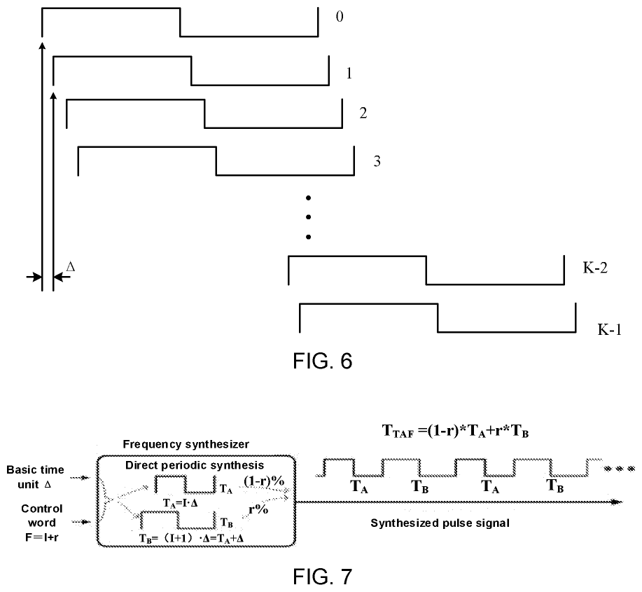

FIG. 6 is a diagram showing waveforms of K reference pulse signals, with uniform spaced phases, generated by the signal generator in FIG. 5. Referring to FIG. 6, waveforms of any two signals are the same (that is, periods and amplitudes thereof are both the same), and waveforms of the K signals are uniformly arranged (that is, the K signals have an equal interval therebetween). A phase difference between any two adjacent signals is a basic time unit Δ, frequencies of the K signals are each fᵢ, and K is an integer greater than 2.

In an implementation manner of the embodiments of the present disclosure, the frequency synthesizer 102 is configured to generate the pulse signal according to the following formula:

$${T}_{TAF} = ( 1 - r ) \times {T}_{A} + r \times {T}_{B} , {T}_{A} = I \times Δ , {T}_{B} = ( I + 1 ) \times Δ \qquad ( 2 )$$

That is, T_{TAF}=(1−r)×|×Δ+r×(I+1)×Δ=(I+r)×Δ, the control word F is a sum of I and r (F=I+r), and the control word here is the FREQ mentioned above.

T_{TAF} is a period of the pulse signal, T_{A} is the first frequency signal (which is also referred to as a first period signal), T_{B} is the second frequency signal (which is also referred to as a second periodic signal); I is the second coefficient that is used for selecting from the K reference pulse signals to synthesize a frequency signal; r is the first coefficient that is used for controlling a probability of occurrence of each of the first frequency signal and the second frequency signal, where r controls a probability of occurrence of T_{B}, and (1−r) controls a probability of occurrence of T_{A}.

For example, in a case where in the control word, I is 3, r is 0.5 . . . (subsequent fractional bits are not shown), in a first period, two reference pulse signals with a phase difference being 3Δ are selected from the K reference pulse signals to synthesize and output T_{A}, and T_{A} is equal to 3Δ (T_{A}=3Δ); in a second period, two reference pulse signals with a phase difference being 4Δ are selected to synthesize and output T_{B}, and T_{B} is equal to 4Δ (T_{B}=4Δ); Δ is the phase difference between any two adjacent signals in the K reference pulse signals with the uniform spaced phases.

In the embodiments of the present disclosure, the control words may be each an integer or a fraction, and each control word may be split into an integral part and a fractional part. The integral part may serve as the second coefficient, and the fractional part may serve as the first coefficient, so as to realize synthesis of the pulse signal. For example, the control word is 5.4 . . . , the integer part thereof is 5, and the fractional part thereof is 0.4 . . . . For another example, the control word is 6, the integer part thereof is 6, and the fractional part thereof is 0.

FIG. 7 is a schematic diagram showing a principle of synthesizing the pulse signal by using the frequency synthesizer. Referring to FIG. 7, the frequency synthesizer uses a concept of Time Average Frequency to synthesize the pulse signal. Hereinafter, synthesis of the first frequency signal is taken as an example for description. The frequency synthesizer receives the control word and the K reference pulse signals with the uniform spaced phases. The control word F is the sum of I and r (F=I+r), where I is the integral part, and r is the fractional part. The phase difference between any two adjacent signals of the K reference pulse signals with the uniform spaced phases is the basic time unit Δ. The frequency synthesizer first constructs, according to the basic time unit Δ and the integral part I of the control word F, two different clock periods T_{A} and T_{B}, T_{A}=I·Δ, T_{B}=(I+1)·Δ, T_{B} is a longer period than T_{A}, which is represented in FIG. 7 that a length of a high level or a low level of T_{B} is longer than that of T_{A}. Then, the frequency synthesizer controls, based on the fractional part r of the control word F, the probability of occurrence of T_{A} and the probability of occurrence of T_{B} (i.e., the proportions of the first frequency signal and the second frequency signal mentioned above), so that the pulse signal is generated.

The fractional part of the control word affects both the probability of occurrence of T_{A} and the probability of occurrence of T_{B}. In a case where the fractional part is 0.5, the probability of occurrence of T_{A} is equal to the probability of occurrence of T_{B}; referring to the pulse signal as shown in FIG. 7, T_{A} and T_{B} appear alternately. In a case where the fractional part is less than 0.5, the probability of occurrence of T_{A} is greater than the probability of occurrence of T_{B}; in a special case where the fractional part is 0, the pulse signal includes only T_{A}. In a case where the fractional part is greater than 0.5, the probability of occurrence of T_{B} is greater than the probability of occurrence of T_{A}.

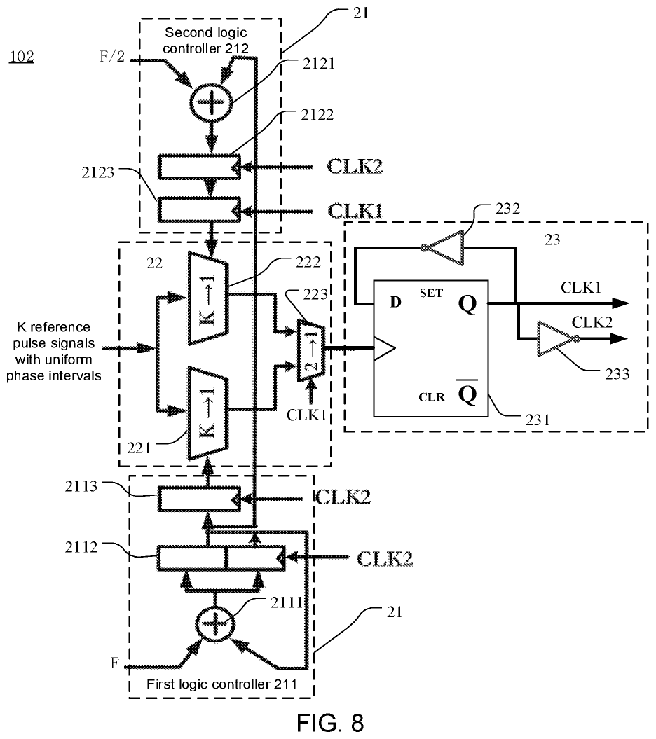

FIG. 8 is a schematic diagram showing a structure of the frequency synthesizer 102 provided in the embodiments of the present disclosure. Referring to FIG. 8, the frequency synthesizer 102 may include a first processing unit 21, a second processing unit 22 and an output unit 23.

The first processing unit 21 is connected to a controller 30 and generates a first control signal and a second control signal based on the control word. The second processing unit 22 is connected to the first processing unit 21, selects a first pulse signal from the reference pulse signals with the uniform spaced phases based on the first control signal, selects a second pulse signal from the reference pulse signals based on the second control signal, and selects one of the first pulse signal and the second pulse signal as an output signal.

The output unit 23 is connected to the second processing unit 22 and generates the pulse signal based on the output signal of the second processing unit 22.

Hereinafter, detailed working processes of the first processing unit 21, the second processing unit 22 and the output unit 23 will be described with reference to FIG. 8.

The first processing unit 21 includes a first logic controller 211 and a second logic controller 212.

Referring to FIG. 8, the first logic controller 211 includes a first adder 2111, a first register 2112 and a second register 2113, and the first register 2112 is connected to the first adder 2111 and the second register 2113. The first logic controller 211 is used for generating the first control signal.

The first adder 2111 adds the control word F and most significant bits (e.g., 5 bits) stored in the first register 2112, and then the addition result is stored in the first register 2112 at a rising edge of a second clock frequency CLK2. Alternatively, the first adder 2111 may add the control word F and all bits stored in the first register 2112, and then the addition result is stored in the first register 2112 at the rising edge of the second clock frequency CLK2. At a next rising edge of the second clock frequency CLK2, the most significant bits stored in the first register 2112 will be stored in the second register 2113 as a selection signal (i.e., the first control signal mentioned above), used for selecting a signal from the K reference pulse signals with the uniform spaced phases as the first pulse signal, of a first K→1 multiplexer 221.

In the addition of the control word F and the most significant bits stored in the first register 2112, assuming that a value in the first register 2112 is less than 1, if a fractional part of the addition result carries, the most significant bits stored in the second register 2113 is (I+1); if the fractional part of the addition result does not carry, the most significant bits stored in the second register 2113 is I. In a case where the most significant bits stored in the second register 2113 are (I+1), the frequency synthesizer outputs T_{B}, and T_{B} is equal to (I+1)·Δ (T_{B}=(I+1)·Δ); in a case where the most significant bits stored in the second register 2113 are I, the frequency synthesizer outputs T_{A}, and T_{A} is equal to I·Δ (T_{A}=I·Δ). It can be seen that outputting whether T_{A} or T_{B} is related to a magnitude of the fractional part of the control word, the less the fractional part of the control word, the less likely the carry occurs, and the greater a probability of outputting T_{A}. On the contrary, the greater a probability of outputting T_{B}.

Here, the first register 2112 may include a first portion storing an integer and a second portion storing a fraction. In the addition, the integral part of the control word F is added to a content in the first portion, and the fractional part of the control word F is added to a content in the second portion. The addition is a binary addition, which is realized by the first adder 2111.

The second logic controller 212 includes a second adder 2121, a third register 2122 and a fourth register 2123. The third register 2122 is connected to the second adder 2121 and the fourth register 2123. The second logic controller 212 is used for generating the second control signal.

The second adder 2121 adds half of the control word F/2 and the most significant bits stored in the third register 2122, and then the addition result is stored in the third register 2122 at the rising edge of the second clock frequency CLK2. After the addition result is stored in the third register 2122, at a rising edge of a first clock frequency CLK1, information stored in the third register 2122 will be stored in the fourth register 2123 as a selection signal (i.e., the second control signal mentioned above), used for selecting a signal from K multi-phase input signals as the second pulse signal, of a second K→1 multiplexer 222. The second clock frequency CLK2 is a signal obtained after the first clock frequency CLK1 passes through a NOT gate.

Referring to FIG. 8, the second processing unit 22 includes the first K→1 multiplexer 221, the second K→1 multiplexer 222 and a 2→1 multiplexer 223. The first K→1 multiplexer 221 and the second K→1 multiplexer 222 each include a plurality of input terminals, a control input terminal and an output terminal. The 2→1 multiplexer 223 includes a control input terminal, an output terminal, a first input terminal and a second input terminal. The output terminal of the first K→1 multiplexer 221 is connected to the first input terminal of the 2→1 multiplexer 223, and the output terminal of the second K→1 multiplexer 222 is connected to the second input terminal of the 2→1 multiplexer 223. The plurality of input terminals of the first K→1 multiplexer 221 and the plurality of input terminals of the second K→1 multiplexer 222 are all connected to the signal generator. The control input terminal of the first K→1 multiplexer 221 is connected to the second register 2113, and the control input terminal of the second K→1 multiplexer 222 is connected to the fourth register 2123.

The control input terminal of the first K→1 multiplexer 221 selects a signal from the K reference pulse signals with the uniform spaced phases as an output signal (i.e., the first pulse signal) under control of the first control signal generated by the first logic controller 211. The control input terminal of the second K→1 multiplexer 222 selects another signal from the K reference pulse signals with the uniform spaced phases as an output signal (i.e., the second pulse signal) under control of the second control signal generated by the second logic controller 212.

The first K→1 multiplexer is taken as an example, the output signal may be selected according to a value (i.e., a value of the first control signal) stored in the second register 2113. For example, the value of the first control signal is 3, a third of the K reference pulse signals with the uniform spaced phases is selected as the output.

The 2→1 multiplexer 223 may select one of the first pulse signal output from the first K→1 multiplexer 221 and the second pulse signal output from the second K→1 multiplexer 222 as an output signal of the 2→1 multiplexer 223 at the rising edge of the first clock frequency CLK1. For example, the first pulse signal is selected from a first rising edge to a second rising edge, the second pulse signal is selected from the second rising edge to a third rising edge, and so on.

Since the 2→1 multiplexer selects the signal from the outputs of the two K→1 multiplexers, the outputs of the two K→1 multiplexers combine to form a new period; since a difference between the first pulse signal and the second pulse signal respectively output by the two K→1 multiplexers is an integer multiple of Δs, and there are two cases where the difference is I×Δ and the difference is (I+1)×Δ, there are two different periods T_{A} and T_{B} in the pulse signal output by the frequency synthesizer.

Referring to FIG. 8, the output unit 23 includes a flip-flop circuit. The flip-flop circuit is used for generating a pulse train. The flip-flop circuit includes a D flip-flop 231, a first inverter 232 and a second inverter 233. The D flip-flop 231 includes a data input terminal, a clock input terminal and an output terminal. The first inverter 232 includes an input terminal and an output terminal. The second inverter 233 includes an input terminal and an output terminal. The clock input terminal of the D flip-flop 231 is connected to the 2→1 multiplexer 223, the data input terminal of the D flip-flop 231 is connected to the output terminal of the first inverter 232, and the output terminal of the D flip-flop 231 is connected to the input terminal of the first inverter 232 and the input terminal of the second inverter 233. The output terminal of the D flip-flop 231 or the output terminal of the second inverter 233 may serve as an output terminal (i.e. a terminal generating the pulse signal) of the frequency synthesizer. Therefore, the pulse signal output by the frequency synthesizer is the first clock frequency CLK1 or the second clock frequency CLK2 in FIG. 8.

In the embodiments of the present disclosure, a first clock signal and a second clock signal are each the first clock frequency CLK1 output by the frequency synthesizer when a different control word is input. Alternatively, the first clock signal and the second clock signal are each the second clock frequency CLK2 output by the frequency synthesizer when a different control word is input.

The clock input terminal of the D flip-flop 231 receives the output from the output terminal of the 2→1 multiplexer 223 and outputs the first clock frequency CLK1 via the output terminal; the input terminal of the first inverter 232 receives the first clock frequency CLK1 and outputs the output signal to the data input terminal of the D flip-flop 231; the input terminal of the second inverter 233 receives the first clock frequency CLK1 and outputs the second clock frequency CLK2 via the output terminal.

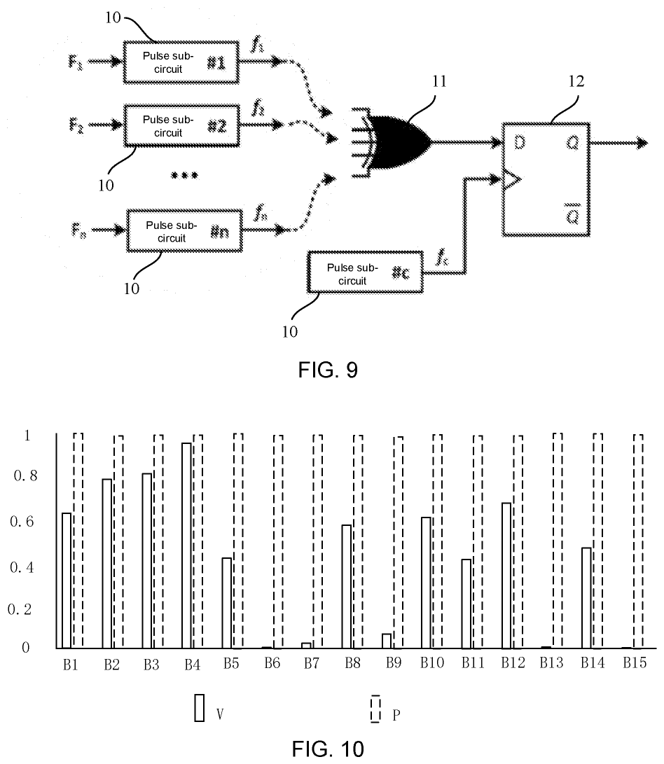

FIG. 9 is a detailed schematic diagram of the random number generating circuit 1 provided in the embodiments of the present disclosure. Referring to FIG. 9, the first processing sub-circuit 11 may include an XOR sub-circuit. The XOR sub-circuit performs the XOR operation on the pulse signals.

The XOR sub-circuit may perform the XOR operation on the frequency pulse signals according to the following formula: a⊕b⊕c⊕ . . . ⊕n; where a to n represent the frequency pulse signals.

In other implementation manners, the first processing sub-circuit 11 may include a plurality of logic operation sub-circuits. For example, the first processing sub-circuit 11 performs XOR processing on a part of the pulse signals, and performs XNOR processing on the other part of the pulse signals, and then, results of the XOR processing and the XNOR processing are processed by NAND as the output of the first processing sub-circuit 11.

As shown in FIG. 9, in a possible implementation manner, the second processing sub-circuit 12 may include a sampling sub-circuit, the sampling sub-circuit is connected to the XOR sub-circuit, and the sampling sub-circuit samples a signal output by the XOR sub-circuit based on the clock pulse signal to obtain a random number sequence.

As shown in FIG. 9, in the random number generating circuit, n pulse sub-circuits 10 (i.e., frequency sub-circuits) generate pulses with different frequencies by controlling respective control words F₁ to Fₙ, respectively, and the first processing sub-circuit combines all waveforms of the pulses with different frequencies together through the logical operation to generate a waveform with a high degree of unpredictability. The unpredictability of the waveform mainly caused by two reasons. First, the K reference pulse signals are input to the frequency synthesizer in each pulse sub-circuit, the reference pulse signals input to the frequency synthesizer each have a different noise effect and a different initial phase, and a noise may affect the waveform; for example, a period of a signal in an ideal state is 20 ms, however, the period may be 19 ms or 21 ms due to an existence of the noise, thereby causing waveforms of the K reference pulse signals to be different; furthermore, different K inputs of the frequency synthesizer are each generated by a different circuit, and the different circuit may generate an input waveform with a different noise and a different initial phase; the initial phase is related to a residual electric quantity of a capacitor in the circuit, and the residual electric quantity of the capacitor is different when a different circuit is switched on, which results in the different initial phases. Second, outputs and initial phases of all frequency synthesizers are different. It is for the above reasons that the mixed waveform has high unpredictability and abnormality.

In addition, since a rising edge or a falling edge of the clock pulse signal is not periodically arranged, using the clock pulse signal may improve randomness of the sampling. A metastable state often occurs in a sampling process of the output of the first processing sub-circuit according to the clock pulse signal, which further increases the unpredictability of the random number. The metastable state occurring in the sampling process refers to a metastable state caused by which a sampling point is exactly at a rising edge or a falling edge of the output signal of the first processing sub-circuit, and in this case, it has randomness that the sampling sub-circuit outputs 0 or 1.

For example, the sampling sub-circuit includes a D flip-flop (DFF). An input terminal of the D flip-flop is connected to the first processing sub-circuit 11, and a control terminal of the D flip-flop is connected to the clock sub-circuit.

Optionally, the random number generating circuit 1 further includes a post processing sub-circuit, the post processing sub-circuit is connected to the frequency synthesizer 102 to perform post processing on the random number signal output by the frequency synthesizer 102, so as to perform correction of probability deviation on the random number signal output by the frequency synthesizer 102.

The probability deviation refers to a deviation between probabilities of occurrence of bits 0 and 1 in the random number signal and probabilities of occurrence of the bits 0 and 1 in a true random case. By performing the correction of probability deviation on the random number signal, a proportion of the bit 0 to the bit 1 in the random number signal output by the random number generating circuit is closer to 1:1, and an arrangement order of the bits 0 and 1 conform to a random distribution, thereby increasing the chaos and the complexity of the random number signal.

The post-processing circuit may use various algorithms, such as a von Neumann correction algorithm, a hash algorithm, a chaotic algorithm, etc.

The random number generator realized by the method passes all of American National Institute of Standards and Technology (NIST) random number test (i.e., an international standard for the random number test), and test results thereof are shown in the following table.

| | B1 | B2 | B3 | B4 | B5 | B6 | B7 | B8 | B9 | B10 | B11 | B12 | B13 | B14 | B15 |
|---|---|---|---|---|---|---|---|---|---|---|---|---|---|---|---|
| C1 | 94 | 95 | 97 | 96 | 115 | 110 | 117 | 117 | 118 | 102 | 14 | 9 | 3 | 3 | 7 |
| C2 | 77 | 99 | 110 | 90 | 97 | 120 | 101 | 97 | 114 | 100 | 6 | 10 | 7 | 5 | 10 |
| C3 | 100 | 111 | 102 | 97 | 96 | 98 | 116 | 106 | 109 | 100 | 15 | 12 | 3 | 8 | 3 |
| C4 | 99 | 89 | 117 | 108 | 106 | 98 | 92 | 88 | 101 | 191 | 9 | 10 | 9 | 10 | 9 |
| C5 | 122 | 88 | 95 | 91 | 97 | 103 | 97 | 98 | 89 | 103 | 8 | 13 | 15 | 6 | 10 |
| C6 | 116 | 99 | 93 | 97 | 115 | 81 | 89 | 91 | 107 | 102 | 13 | 9 | 6 | 6 | 14 |
| C7 | 108 | 102 | 93 | 99 | 89 | 109 | 101 | 94 | 100 | 84 | 8 | 6 | 4 | 5 | 22 |
| C8 | 99 | 117 | 100 | 103 | 95 | 103 | 113 | 110 | 88 | 93 | 11 | 15 | 7 | 8 | 13 |
| C9 | 93 | 90 | 87 | 102 | 85 | 97 | 89 | 105 | 92 | 81 | 10 | 7 | 10 | 7 | 5 |
| C10 | 92 | 110 | 106 | 117 | 105 | 81 | 85 | 94 | 82 | 104 | 6 | 9 | 4 | 10 | 7 |
| V | 0.62 | 0.78 | 0.81 | 0.95 | 0.42 | 0.0008 | 0.03 | 0.57 | 0.08 | 0.60 | 0.41 | 0.67 | 0.007 | 0.46 | 0.001 |
| P | 0.99 | 0.98 | 0.99 | 0.99 | 0.99 | 0.99 | 0.99 | 0.98 | 0.98 | 0.99 | 0.98 | 0.98 | 1 | 1 | 0.99 |

In the above table, B1 to B15 represent items of the NIST test, which respectively are frequency, block frequency, cumulatives sums, runs, longest run, rank, FFT, nonoverlapping, approximate entropy, serial, overlapping, universal, random excursions, random variant and linear complexity. V represents a value (P_VALUE), and P represents a proportion of passing the test (PROPORTION). P_VALUE is uniformly divided into ten sections (i.e., 0 to 0.1, 0.1 to 0.2, . . . , 0.9 to 1.0) from 0 to 1; the ten sections correspond to C1 to C10, respectively. For example, 1000 data packages are run during the NIST test, each data package has a value, and each value is within a section of C1 to C10; then, the number of data packages within each section is counted to obtain the values respectively corresponding to C1 to C10 in the above table. P_VALUE is obtained based on values in each section. For example, P_VALUE is obtained, by using the chi-square distribution, based on the values in each section.

FIG. 10 is a diagram showing a NIST test of the random number generated by the random number generator provided in the embodiments of the present disclosure. That is, the results from the above table are graphically visualized. It can be seen from the above table and FIG. 10 that in 15 results of B1 to B15, each P_VALUE is greater than 0.0001, and each PROPORTION is greater than 0.98, which means that the random number generator passes the NIST test.

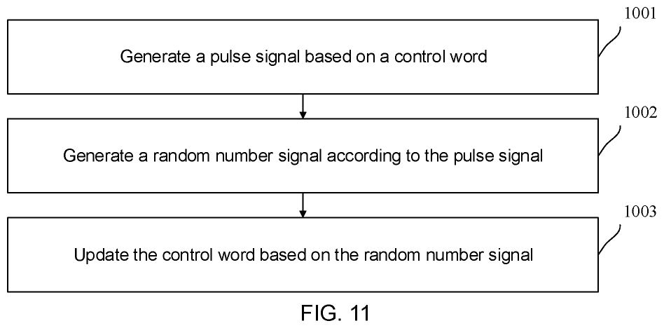

FIG. 11 is a flow diagram of a random number generating method provided in embodiments of the present disclosure. Referring to FIG. 11, the random number generating method includes the following steps.

In 1001, a pulse signal is generated based on a control word, the pulse signal includes a first frequency signal and a second frequency signal that appear alternately, and proportions of the first frequency signal and the second frequency signal are controlled by the control word.

In 1002, a random number signal is generated according to the pulse signal.

In 1003, the control word is updated based on the random number signal.

In the embodiments of the present disclosure, the control word of a random number generating circuit is updated based on the random number signal output by the random number generating circuit, so that the control word of the random number generating circuit is always changing. Compared with a control word of a random number generating circuit that is unchanged, randomness of the random number generating circuit of the embodiments of the present disclosure is fundamentally improved, so that randomness of the random number output by a random number generator is improved.

In some possible implementation manners, updating the control word based on the random number signal includes:
performing frequency division on the random number signal, and outputting a frequency division signal obtained by the frequency division;
determining a linear congruence signal by using the frequency division signal; and
updating the control word by using the linear congruence signal.
Determining the linear congruence signal by using the frequency division signal includes:
performing linear congruence processing on a linear congruence signal of a previous period and performing XOR operation on a signal composed of a result of the linear congruence processing and the frequency division signal to obtain a linear congruence signal of a current period.

For example, updating the control word by using the linear congruence signal includes:
updating the first coefficient by using N bits of the linear congruence signal; N being less than or equal to the number of bits of a first coefficient of the control word, and N being greater than half of the number of bits of the first coefficient.

For example, the first coefficient is fractional bits of the control word, the number of fractional bits of the control word is 8, and N is equal to 8.

In some possible implementation manners, the pulse signal includes frequency pulse signals and a clock pulse signal.

Generating the random number signal according to the pulse signal includes:
performing a first processing on the frequency pulse signals; the first processing including at least one of XOR, XNOR or NAND; and
sampling output of the first processing based on the clock pulse signal to obtain the random number signal.

Updating the control word by using the linear congruence signal includes:
periodically updating a control word of each pulse sub-circuit by using the linear congruence signal.

For example, control words of a plurality of pulse sub-circuits are updated in turn, and a control word of one of the plurality of pulse sub-circuits is updated in each period.

For example, a process of outputting the pulse signal by the pulse sub-circuit includes:
generating reference pulse signals with uniform spaced phases in response to an initial pulse signal; and
generating the pulse signal in response to the reference pulse signals and the control word.

The control word includes a first coefficient and a second coefficient.

The pulse signal includes the first frequency signal generated based on the reference pulse signals and the second coefficient and the second frequency signal generated based on the reference pulse signals and the second coefficient, and the proportions of the first frequency signal and the second frequency signal in the pulse signal are controlled by the first coefficient.

It will be noted that the random number generating method provided in the above embodiments belongs to the same concept as the random number generator provided in the above embodiments, and an implementation process of the random number generating method is described in detail in the embodiments about the random number generator, which will not be repeated here.

The above embodiments are merely exemplary embodiments of the present disclosure, and are not intended to limit the present disclosure. Any modification, equivalent replacement and improvement made within the spirits and the principle of the present disclosure shall be included in the protection scope limited in the claims of the present disclosure.

1. A random number generator, comprising:
a random number generating circuit used for generating a pulse signal based on a control word and generating a random number signal according to the pulse signal; the pulse signal including a first frequency signal and a second frequency signal that appear alternately, and proportions of the first frequency signal and the second frequency signal being controlled by the control word; and
a feedback update circuit used for updating the control word based on the random number signal output by the random number generating circuit.

2. The random number generator according to claim 1, wherein the feedback update circuit includes:
a frequency division sub-circuit used for performing frequency division on the random number signal generated by the random number generating circuit and outputting a frequency division signal obtained by the frequency division;
a linear congruence sub-circuit used for determining a linear congruence signal by using the frequency division signal output by the frequency division sub-circuit; and
a feedback output sub-circuit used for updating the control word by using the linear congruence signal output by the linear congruence sub-circuit;
wherein the frequency division sub-circuit is electrically connected to the linear congruence sub-circuit, the feedback output sub-circuit and the random number generating circuit, and the feedback output sub-circuit is electrically connected to the linear congruence sub-circuit and the random number generating circuit.

3. The random number generator according to claim 2, wherein the linear congruence sub-circuit is used for determining the linear congruence signal by:
performing linear congruence processing on a linear congruence signal of a previous period, and performing an exclusive OR (XOR) operation on a signal composed of a result of the linear congruence processing and the frequency division signal output by the frequency division sub-circuit, so as to obtain a linear congruence signal of a current period.

4. The random number generator according to claim 2, wherein the control word includes a first coefficient, and the first coefficient is used for controlling the proportions of the first frequency signal and the second frequency signal in the pulse signal;
the feedback output sub-circuit is used for updating the first coefficient by using N bits of the linear congruence signal output by the linear congruence sub-circuit; N is less than or equal to a number of bits of the first coefficient, and N is greater than half of the number of bits of the first coefficient.

5. The random number generator according to claim 4, wherein the first coefficient is fractional bits of the control word, a number of fractional bits of the control word is 8, and N is equal to 8.

6. The random number generator according to claim 2, wherein the random number generating circuit includes:
a plurality of pulse sub-circuits, one of the plurality of pulse sub-circuits being a clock sub-circuit used for outputting a clock pulse signal, and remaining pulse sub-circuits of the plurality of pulse sub-circuits being each a frequency sub-circuit used for outputting a frequency pulse signal;
a first processing sub-circuit electrically connected to the remaining pulse sub-circuits and used for performing first processing on the frequency pulse signals output by the frequency sub-circuits; wherein the first processing includes at least one of XOR, exclusive NOR (XNOR) or NOT AND (NAND); and
a second processing sub-circuit electrically connected to the clock pulse signal and used for sampling an output of the first processing sub-circuit based on the clock pulse signal to obtain the random number signal.

7. The random number generator according to claim 6, wherein the feedback output sub-circuit is used for periodically updating control words of the remaining pulse sub-circuits by using the linear congruence signal output by the linear congruence sub-circuit.

8. The random number generator according to claim 7, wherein the feedback output sub-circuit is used for updating the control words of the remaining pulse sub-circuits in turn; the feedback output sub-circuit updates a control word of one of the remaining pulse sub-circuits in each period.

9. The random number generator according to claim 6, wherein a pulse sub-circuit of the remaining pulse sub-circuits includes:
a signal generator and a frequency synthesizer; the frequency synthesizer being electrically connected to the signal generator, the feedback update circuit and the first processing sub-circuit;
wherein the signal generator is used for generating reference pulse signals with uniform spaced phases in response to an initial pulse signal;
the frequency synthesizer is used for generating the pulse signal in response to the reference pulse signals and the control word;
wherein the control word includes a first coefficient and a second coefficient;
the pulse signal includes the first frequency signal generated based on the reference pulse signals and the second coefficient and the second frequency signal generated based on the reference pulse signals and the second coefficient, and the proportions of the first frequency signal and the second frequency signal in the pulse signal are controlled by the first coefficient.

10. A random number generating method, comprising:
generating a pulse signal based on a control word; the pulse signal including a first frequency signal and a second frequency signal that appear alternately, and proportions of the first frequency signal and the second frequency signal being controlled by the control word;
generating a random number signal according to the pulse signal; and
updating the control word based on the random number signal.

11. The random number generating method according to claim 10, wherein updating the control word based on the random number signal includes:
performing frequency division on the random number signal;
outputting a frequency division signal obtained by the frequency division;
determining a linear congruence signal by using the frequency division signal; and
updating the control word by using the linear congruence signal.

12. The random number generating method according to claim 11, wherein determining the linear congruence signal by using the frequency division signal includes:
performing linear congruence processing on a linear congruence signal of a previous period; and
performing an exclusive OR (XOR) operation on a signal composed of a result of the linear congruence processing and the frequency division signal, so as to obtain a linear congruence signal of a current period.

13. The random number generating method according to claim 11, wherein the control word includes a first coefficient, and the first coefficient is used for controlling the proportions of the first frequency signal and the second frequency signal in the pulse signal;
updating the control word by using the linear congruence signal includes:
updating the first coefficient by using N bits of the linear congruence signal; wherein N is less than or equal to a number of bits of the first coefficient, and N is greater than half of the number of bits of the first coefficient.

14. The random number generating method according to claim 13, wherein the first coefficient is fractional bits of the control word, a number of fractional bits of the control word is 8, and N is equal to 8.

15. The random number generating method according to claim 11, wherein the pulse signal includes frequency pulse signals and a clock pulse signal;
generating the random number signal according to the pulse signal includes:
performing first processing on the frequency pulse signals, the first processing including at least one of XOR, exclusive NOR (XNOR) or NOT AND (NAND); and
sampling an output of the first processing based on the clock pulse signal to obtain the random number signal.

16. The random number generator according to claim 1, wherein the feedback update circuit is implemented by using a 32-bit field programmable gate array.

17. The random number generator according to claim 6, wherein in the plurality of pulse sub-circuits, a pulse sub-circuit generating a pulse signal with a minimum frequency is the clock sub-circuit.

18. The random number generator according to claim 6, wherein the plurality of pulse sub-circuits are each a digitally controlled oscillator.

19. The random number generator according to claim 6, wherein the second processing sub-circuit includes a sampling sub-circuit; the sampling sub-circuit includes a D flip-flop, an input terminal of the D flip-flop is connected to the first processing sub-circuit, and a control terminal of the D flip-flop is connected to the clock sub-circuit.

20. The random number generator according to claim 9, the signal generator is a ring oscillator.
